(19) United States
(12) Patent Application Publication
(10) Pub. No.: US 2026/0029461 A1
(43) Pub. Date: Jan. 29, 2026

(54) SWITCH APPARATUS AND TESTING APPARATUS

(71) Applicant: ADVANTEST CORPORATION, Tokyo (JP)

(72) Inventor: Satoshi KOYAMA, Miyagi (JP)

(21) Appl. No.: 19/218,598

(22) Filed: May 26, 2025

(30) Foreign Application Priority Data
Jul. 23, 2024 (JP) 2024-117451

(51) Int. Cl. G01R 31/28; G01R 1/20

(52) U.S. Cl. CPC G01R 31/2844; G01R 1/203

(57) ABSTRACT

Provided is a switch apparatus which electrically connects or disconnects across a first terminal and a second terminal, the switch apparatus including a plurality of main switches connected in series between the first terminal and the second terminal, a first sensing buffer unit to which a first voltage at the first terminal is input and which outputs a first sensing voltage in accordance with the first voltage, and a bias circuit which divides, according to a number of the plurality of main switches, a potential difference between a voltage in accordance with a second voltage at the second terminal and the first sensing voltage into voltages and applies each of the voltages divided to a corresponding one of the plurality of main switches.

The contents of the following patent application(s) are incorporated herein by reference: NO. 2024-117451 filed in JP on Jul. 23, 2024.

### BACKGROUND

### 1. Technical Field

The present invention relates to a switch apparatus and a testing apparatus.

### 2. Related Art

Patent Documents 1 to 3 describe a semiconductor switch circuit and the like.

### PRIOR ART DOCUMENTS

### Patent Documents

Patent Document 1: Japanese Patent Application Publication No. 2015-065504
Patent Document 2: International Publication No. 2022/030375
Patent Document 3: International Publication No. 2015/011949

### BRIEF DESCRIPTION OF THE DRAWINGS

FIG. 1 illustrates a first exemplary configuration of a switch apparatus 10 according to the present embodiment.

FIG. 2 illustrates a second exemplary configuration of the switch apparatus 10 according to the present embodiment.

FIG. 3 illustrates a third exemplary configuration of the switch apparatus 10 according to the present embodiment.

FIG. 4 illustrates a fourth exemplary configuration of the switch apparatus 10 according to the present embodiment.

FIG. 5 illustrates a fifth exemplary configuration of the switch apparatus 10 according to the present embodiment.

FIG. 6 illustrates a configuration example of a testing apparatus 400 according to the present embodiment together with a device under test 410.

### DESCRIPTION OF EXEMPLARY EMBODIMENTS

Hereinafter, the present invention will be described by way of embodiments of the invention. However, the following embodiments are not for limiting the invention according to the claims. In addition, not all combinations of features described in the embodiments are necessarily essential to a solution of the invention.

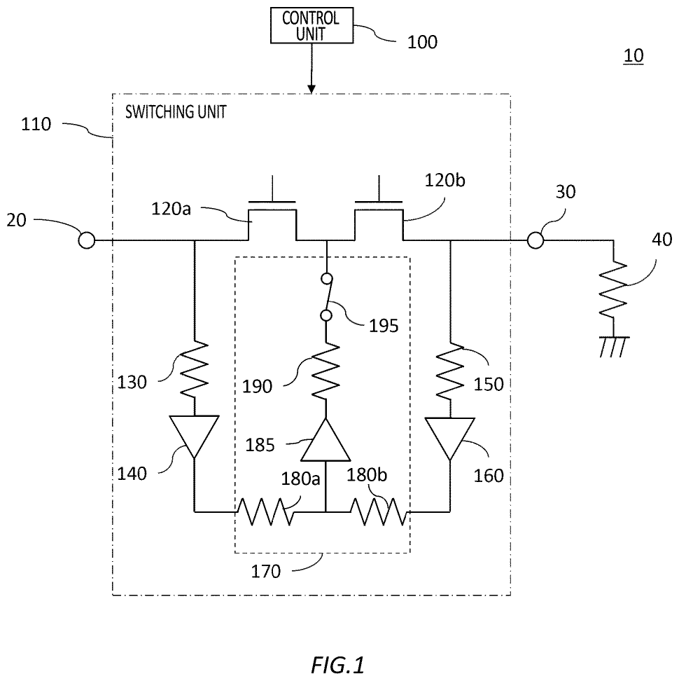

FIG. 1 illustrates a first exemplary configuration of a switch apparatus 10 according to the present embodiment. The switch apparatus 10 electrically connects or disconnects across a first terminal 20 and a second terminal 30. In the switch apparatus 10, the first terminal 20 is connected to a component of a testing apparatus, the second terminal 30 is connected to a load 40 such as a device under test, and a current ranging from a direct current to a high frequency can be caused to flow between the first terminal 20 and the second terminal 30. In the switch apparatus 10, the current can be caused to flow from the first terminal 20 to the second terminal 30 in a single direction or to flow between the first terminal 20 and the second terminal 30 in both directions. The switch apparatus 10 includes a control unit 100 and a switching unit 110.

The control unit 100 is connected to the switching unit 110. The control unit 100 supplies, to the switching unit 110, a voltage for electrically connecting or disconnecting across the first terminal 20 and the second terminal 30 according to a control signal input from the outside.

The switching unit 110 electrically connect or disconnects across the first terminal 20 and the second terminal 30 according to the voltage supplied from the control unit 100. The switching unit 110 includes a plurality of main switches 120, a first resistance 130, a first sensing buffer unit 140, a second resistance 150, a second sensing buffer unit 160, and a bias circuit 170. The switch apparatus 10 has a configuration for dividing a first voltage to each of the main switches 120 while reducing off-leak current during a period in which the plurality of main switches 120 are off.

The plurality of main switches 120 are connected in series between the first terminal 20 and the second terminal 30. The plurality of main switches 120 are turned on or off according to a gate voltage supplied from the control unit 100. When the plurality of main switches 120 are turned on, a current flows between the first terminal 20 and the second terminal 30. As an example, each of the main switches 120 is a semiconductor switch such as a field effect transistor (FET) in which a source and a drain are connected between the first terminal 20 and the second terminal 30. According to the present embodiment, the plurality of main switches 120 include a first main switch 120a and a second main switch 120b. The first main switch 120a is connected between the first terminal 20 and the second main switch 120b. The second main switch 120b is connected to the second terminal 30.

The first resistance 130 is connected between the first terminal 20 and the first sensing buffer unit 140. One end of the first resistance 130 may be connected to a node between the first terminal 20 and the first main switch 120a, and another end may be connected to an input of the first sensing buffer unit 140. Since a high frequency signal input from the first terminal 20 hardly flows in the first resistance 130, an influence of the high frequency signal on the first sensing buffer unit 140 can be reduced. As an example, the first resistance 130 has a resistance value of 2 kΩ or more and 10 kΩ or less.

An output of the first sensing buffer unit 140 is connected the bias circuit 170. The first voltage at the first terminal 20 is input to the first sensing buffer unit 140, and the first sensing buffer unit 140 outputs a first sensing voltage in accordance with the first voltage. As an example, the first sensing buffer unit 140 is a voltage follower circuit using an operational amplifier. The first sensing buffer unit 140 may output, to the bias circuit 170, the first sensing voltage that has a same voltage value of the first voltage at the first terminal 20. For example, the first sensing buffer unit 140 has a current amplification function (that is, a buffer function) such that the first voltage at the first terminal 20 is hardly reduced (which hardly becomes a load for the first voltage).

One end of the second resistance 150 is connected to a node between the second terminal 30 and the second main switch 120b, and another end is connected to an input of the second sensing buffer unit 160. The second resistance 150 may have a same resistance value as the first resistance 130 and as an example, have a resistance value of 2 kΩ or more and 10 kΩ or less.

An output of the second sensing buffer unit 160 is connected to the bias circuit 170. A second voltage at the second terminal 30 may be input to the second sensing buffer unit 160, and the second sensing buffer unit 160 may output a second sensing voltage in accordance with the second voltage. As an example, the second sensing buffer unit 160 is a voltage follower circuit using an operational amplifier. The second sensing buffer unit 160 may output, to the bias circuit 170, the second sensing voltage of a same voltage value as the second voltage at the second terminal 30. For example, the second sensing buffer unit 160 has a current amplification function (that is, a buffer function) such that the second voltage at the second terminal 30 is hardly reduced (which hardly becomes a load for the second voltage).

An output of the bias circuit 170 is connected between the plurality of main switches 120. The bias circuit 170 divides, according to a number of the main switches 120, a potential difference between a voltage in accordance with the second voltage at the second terminal 30 and the first sensing voltage into voltages and applies each of the voltages divided to a corresponding one of the main switches 120. The bias circuit 170 may divide a potential difference between the first sensing voltage and the second sensing voltage into voltages according to the number of the main switches 120 and applies each of the voltages divided to the corresponding one of the main switches 120. According to the present embodiment, the output of the bias circuit 170 is connected between the first main switch 120a and the second main switch 120b, and the bias circuit 170 may apply the divided voltage between the first main switch 120a and the second main switch 120b. The bias circuit 170 includes a plurality of voltage dividing resistors 180, one or more bias buffer units 185, a bias resistor 190, and a bias switch 195.

The plurality of voltage dividing resistors 180 are connected in series to each other between the output of the first sensing buffer unit 140 and the output of the second sensing buffer unit 160. The plurality of voltage dividing resistors 180 are respectively connected to the plurality of main switches 120 in parallel. A same number of the plurality of voltage dividing resistors 180 as a number of the main switches 120 may be arranged. According to the present embodiment, two voltage dividing resistors 180a and 180b are respectively connected to two main switch 120a and 120b in parallel. The plurality of voltage dividing resistors 180 may divide the potential difference between the first sensing voltage and the second sensing voltage into voltages. A resistance value of each of the plurality of voltage dividing resistors 180 may be 1 kΩ or more and 10 kΩ or less or may be identical to each other. The resistance value of each of the plurality of voltage dividing resistors 180 may be lower than a resistance value of the first resistance 130. With the voltage dividing resistors 180 having such a resistance value, the first voltage can be efficiently divided to each of the main switches 120.

An input of the one or more bias buffer units 185 is connected to a node between the plurality of voltage dividing resistors 180. The one or more bias buffer units 185 may apply each of the voltages divided by the plurality of voltage dividing resistors 180 to the corresponding one of the main switches 120. As an example, the bias buffer unit 185 is a voltage follower circuit using an operational amplifier. The bias buffer unit 185 may receive a voltage at the node between the plurality of voltage dividing resistors 180 and apply a voltage having a same voltage value as the received voltage to a node between the plurality of main switches 120. According to the present embodiment, the bias buffer unit 185 may apply a voltage at a node between the voltage dividing resistors 180a and 180b to a node between the first main switch 120a and the second main switch 120b. For example, the bias buffer unit 185 may have a current amplification function (that is, a buffer function) such that the voltage at the node between the voltage dividing resistor 180a and 180b is hardly reduced. Here, (the number of the main switches 120-1) (according to the present embodiment, 2−1=1) bias buffer unit 185 may be arranged. A current drive capability of the bias buffer unit 185 may be higher than a current drive capability of at least one the first sensing buffer unit 140 or the second sensing buffer unit 160. The current drive capability is a maximum value of a current amount that can be supplied (can be output) to the load, and its unit is mA. The current drive capability of the bias buffer unit 185 is 0.1 mA or more and 100 mA or less as an example. With this configuration, the voltages output by the first sensing buffer unit 140 and the second sensing buffer unit 160 can be efficiently applied to the main switches 120.

An output of the bias buffer unit 185 may be stopped by the control unit 100 in response to at least one of the plurality of main switches 120 having been turned on. For example, at least one of the plurality of main switches 120 may be turned on by the control unit 100 after the output of the bias buffer unit 185 is stopped. The output of the bias buffer unit 185 may be stopped when the control unit 100 turns off the bias switch 195. By turning the output of the bias circuit 170 off while the main switch 120 is turned on in this manner, the influence of the bias circuit 170 on the signal passing through the main switch 120 can be avoided.

The bias resistor 190 is connected to the output of the bias buffer unit 185. The bias resistor 190 may have a resistance value higher than a resistance value of at least one of the first resistance 130 or the second resistance 150.

The bias switch 195 is connected between the bias resistor 190 and the node between the plurality of main switches 120. The bias switch 195 may be controlled to be on or off according to a signal supplied from the control unit 100. The bias switch 195 can stop or start the output of the bias buffer unit 185 to the node between the main switches 120. When the bias switch 195 is turned on, the bias buffer unit 185 can apply a voltage to the node between the main switches 120. When the bias switch 195 is turned off, the bias buffer unit 185 stops applying the voltage between the main switches 120. The bias switch 195 may be turned on while all of the plurality of main switches 120 are off by the control unit 100, and may be turned off while at least one of the plurality of main switches 120 is on.

As an example, when a first voltage Vin at the first terminal 20 is input to the switch apparatus 10 while the main switches 120a and 120b are off, the first sensing buffer unit 140 outputs the first sensing voltage Vin. On the other hand, the second sensing buffer unit 160 outputs a second voltage Vout (═O) at the second terminal 30. In this case, a voltage Vin/2 at the node between the voltage dividing resistors 180a and 180b is applied to the node between the main switches 120 by the bias buffer unit 185, and each of the main switches 120 is applied with the voltage Vin/2. Since the current from the first terminal 20 hardly flows through the first sensing buffer unit 140 even in a case of the direct current, the off-leak current of the switch apparatus 10 can be suppressed to approximately 1 nA to 10 nA.

The switch apparatus 10 in the present embodiment can reduce the off-leak current when the DC current flows in particular while the plurality of main switches 120 are off. In addition, the switch apparatus 10 reduces concentration of the first voltage to the first main switch 120a on the first terminal 20 to which the component such as the testing apparatus is connected, so that an off-breakdown voltage of the entire switch apparatus 10 can be improved. In addition, since the first sensing buffer unit 140 and the bias buffer unit 185 output the voltages in two steps, a voltage value of the power supply which supplies electric power for the output of each of the first sensing buffer unit 140 and the bias buffer unit 185 can be set to be lower than that of the first voltage (for example, a voltage value at half of the first voltage).

Note that a configuration may be adopted in which the switch apparatus 10 does not include the bias switch 195, and the output of the bias buffer unit 185 may be stopped when the control unit 100 turns off the power supply which supplies the electric power for the output of the bias buffer unit 185.

In addition, the output of the first sensing buffer unit 140 may be stopped in response to at least one of the plurality of main switches 120 having been turned on. For example, at least one of the plurality of main switches 120 may be turned on after the output of the first sensing buffer unit 140 is stopped by control of the control unit 100. In this case, the first sensing buffer unit 140 may include a switch for output control between the output and the bias circuit 170. The output of the first sensing buffer unit 140 may be stopped by turning off the switch for output control. In addition, the output of the first sensing buffer unit 140 may be stopped by the control unit 100 by turning off the power supply which supplies the electric power to the first sensing buffer unit 140. Note that the output of the second sensing buffer unit 160 may be stopped similarly as in the first sensing buffer unit 140. Such a configuration for stopping the output of the first sensing buffer unit 140 or the second sensing buffer unit 160 is useful when the switch apparatus 10 does not include the bias buffer unit 185 and the bias switch 195.

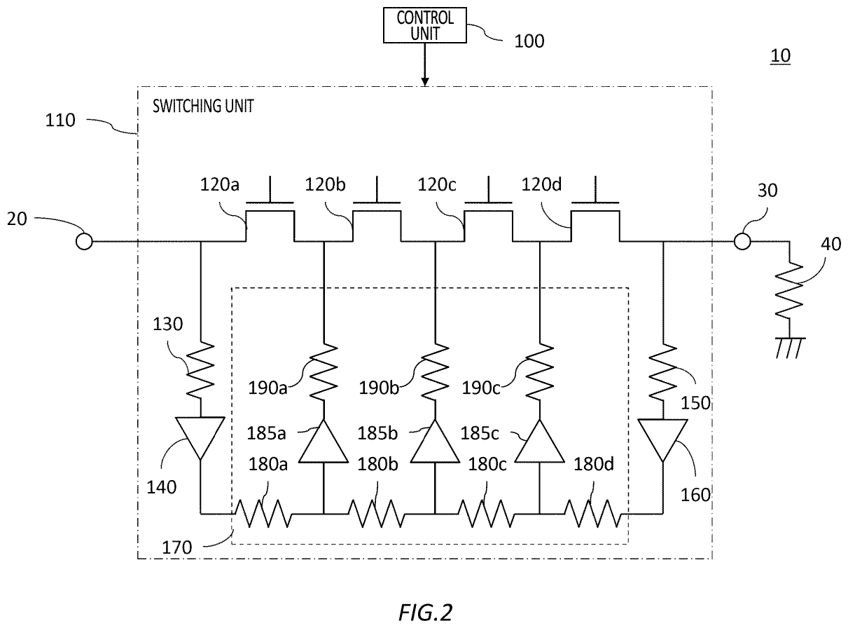

FIG. 2 illustrates a second exemplary configuration of the switch apparatus 10 according to the present embodiment. The switch apparatus 10 of the second exemplary configuration has a configuration and an operation similar to those of the switch apparatus 10 of the first exemplary configuration, but note that the switch apparatus 10 includes more main switches 120. Hereinafter, a difference from the first exemplary configuration will be mainly described.

The switching unit 110 of the switch apparatus 10 includes the first main switch 120a, the second main switch 120b, a third main switch 120c, a fourth main switch 120d, the first resistance 130, the first sensing buffer unit 140, the second resistance 150, the second sensing buffer unit 160, and the bias circuit 170.

The first main switch 120a, the second main switch 120b, the third main switch 120c, and the fourth main switch 120d are connected in series to each other between the first terminal 20 and the second terminal 30. Each of the first main switch 120a, the second main switch 120b, the third main switch 120c, and the fourth main switch 120d may be similar to the first main switch 120a or the second main switch 120b of the first exemplary configuration.

The first resistance 130, the first sensing buffer unit 140, the second resistance 150, and the second sensing buffer unit 160 may respectively have configurations similar to the first resistance 130, the first sensing buffer unit 140, the second resistance 150, and the second sensing buffer unit 160 of the first exemplary configuration and similarly operate.

The bias circuit 170 includes a plurality of voltage dividing resistors 180, a first bias buffer unit 185a, a second bias buffer unit 185b, a third bias buffer unit 185c, a first bias resistor 190a, a second bias resistor 190b, and a third bias resistor 190c.

The plurality of voltage dividing resistors 180 are connected in series to each other between the output of the first sensing buffer unit 140 and the output of the second sensing buffer unit 160. Four voltage dividing resistors 180a, 180b, 180c, and 180d are respectively connected to the first main switch 120a, the second main switch 120b, the third main switch 120c, and the fourth main switch 120d in parallel. The resistance value of each of the plurality of voltage dividing resistors 180 may be 1 k (2 or more and 10 kΩ or less or may be identical to each other. The resistance value of each of the plurality of voltage dividing resistors 180 may be lower than the resistance value of the first resistance 130.

Inputs of the first bias buffer unit 185a, the second bias buffer unit 185b, and the third bias buffer unit 185c are respectively connected to different nodes between the plurality of voltage dividing resistors 180. Each of the first bias buffer unit 185a, the second bias buffer unit 185b, and the third bias buffer unit 185c may have a configuration similar to the bias buffer unit 185 of the first exemplary configuration and similarly operate. The first bias buffer unit 185a may apply a voltage divided by the plurality of voltage dividing resistors 180 to the node between the first main switch 120a and the second main switch 120b. The second bias buffer unit 185b may apply a voltage divided by the plurality of voltage dividing resistors 180 to a node between the second main switch 120b and the third main switch 120c. The third bias buffer unit 185c may apply a voltage divided by the plurality of voltage dividing resistors 180 to a node between the third main switch 120c and the fourth main switch 120d. A current drive capability of each of the first bias buffer unit 185a, the second bias buffer unit 185b, and the third bias buffer unit 185c may be higher than a current drive capability of the first sensing buffer unit 140 and the second sensing buffer unit 160.

The outputs of the first bias buffer unit 185a, the second bias buffer unit 185b, and the third bias buffer unit 185c may be stopped by the control unit 100 in response to at least one of the first main switch 120a, the second main switch 120b, the third main switch 120c, or the fourth main switch 120d having been turned on. The outputs of the first bias buffer unit 185a, the second bias buffer unit 185b, and the third bias buffer unit 185c may be similarly stopped as in the bias buffer unit 185 of the first exemplary configuration. The switch apparatus 10 may further include the bias switch 195 similar to that of the first exemplary configuration between the output of the first bias buffer unit 185a and the node between the first main switch 120a and the second main switch 120b. The switch apparatus 10 may further include the bias switch 195 similar to that of the first exemplary configuration between the output of the second bias buffer unit 185b and the node between the second main switch 120b and the third main switch 120c. The switch apparatus 10 may further include the bias switch 195 similar to that of the first exemplary configuration between the output of the third bias buffer unit 185c and the node between the third main switch 120c and the fourth main switch 120d.

The first bias resistor 190a, the second bias resistor 190b, and the third bias resistor 190c are respectively connected to the outputs of the first bias buffer unit 185a, the second bias buffer unit 185b, and the third bias buffer unit 185c. Each of the first bias resistor 190a, the second bias resistor 190b, and the third bias resistor 190c may have a resistance value higher than a resistance value of at least one of the first resistance 130 or the second resistance 150.

The switch apparatus 10 of the present embodiment turns on the output of the bias circuit 170 (the first bias buffer unit 185a, the second bias buffer unit 185b, and the third bias buffer unit 185c) while the first main switch 120a, the second main switch 120b, the third main switch 120c, and the fourth main switch 120d are turned off. With this configuration, the off-leak current can be reduced, and the concentration of the first voltage to the first main switch 120a is reduced by the voltage division, so that the off-breakdown voltage of the entire switch apparatus 10 can be improved.

Note that the switch apparatus 10 may include five or more main switches 120 connected in series and in this case, may similarly include the bias buffer unit 185, voltage dividing resistor 180, and the bias resistor 190 corresponding to each of the main switches 120.

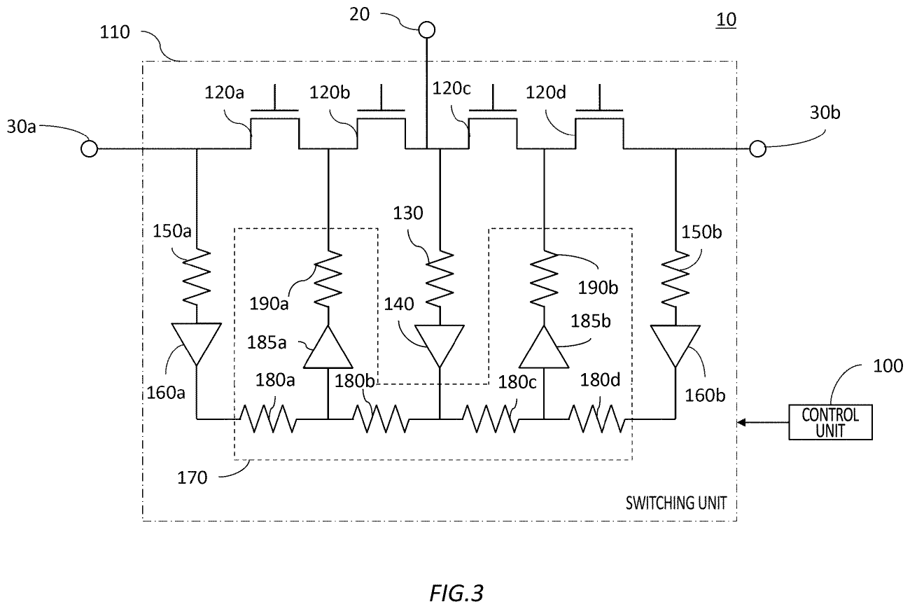

FIG. 3 illustrates a third exemplary configuration of the switch apparatus 10 according to the present embodiment. The switch apparatus 10 of the third exemplary configuration has a configuration and an operation similar to those of the switch apparatus 10 of the second exemplary configuration, but note that the switch apparatus 10 is a single-pole double-throw (SPDT). Hereinafter, a difference from the second exemplary configuration will be mainly described.

The switch apparatus 10 may include a plurality of second terminals 30 arranged for the first terminal 20 concerned therewith, a plurality of second sensing buffer units 160 respectively corresponding to the plurality of second terminals 30, and a plurality of second resistances 150 respectively corresponding to the plurality of second sensing buffer units 160. According to the present embodiment, the plurality of second terminals 30 include a second terminal 30a and a second terminal 30b. The plurality of second sensing buffer units 160 include a second sensing buffer unit 160a and a second sensing buffer unit 160b. The plurality of second resistances 150 include a second resistance 150a and a second resistance 150b.

The first main switch 120a and the second main switch 120b are connected in series to each other between the first terminal 20 and the second terminal 30a. The third main switch 120c and the fourth main switch 120d are connected in series to each other between the first terminal 20 and the second terminal 30b.

The input of the first sensing buffer unit 140 is connected to the node between the second main switch 120b and the third main switch 120c via the first resistance 130, and the output is connected to a node between the plurality of voltage dividing resistors 180b and 180c. The first sensing buffer unit 140 may have a configuration similar to the first sensing buffer unit 140 in the first exemplary configuration and similarly operate.

An input of the second sensing buffer unit 160a is connected to a node between the second terminal 30a and the first main switch 120a via the second resistance 150a, and an output is connected to the voltage dividing resistor 180a. An input of the second sensing buffer unit 160b is connected to a node between the second terminal 30b and the fourth main switch 120d via the second resistance 150b, and an output is connected to the voltage dividing resistor 180d. Each of the second sensing buffer unit 160a and the second sensing buffer unit 160b may have a configuration similar to the second sensing buffer unit 160 of the first exemplary configuration and similarly operate.

The bias circuit 170 includes a plurality of voltage dividing resistors 180, the first bias buffer unit 185a, the second bias buffer unit 185b, the first bias resistor 190a, and the second bias resistor 190b. The plurality of voltage dividing resistors 180 are connected in series to each other between the output of the first sensing buffer unit 140 and an output of the second sensing buffer unit 160a and between the output of the first sensing buffer unit 140 and an output of the second sensing buffer unit 160b. The plurality of voltage dividing resistors 180a, 180b, 180c, and 180d are respectively connected to the first main switch 120a, the second main switch 120b, the third main switch 120c, and the fourth main switch 120d in parallel. The resistance value of each of the plurality of voltage dividing resistors 180 may be 1 kΩ or more and 10 kΩ or less or may be identical to each other. The resistance value of each of the plurality of voltage dividing resistors 180 may be lower than the resistance value of the first resistance 130.

An input of the first bias buffer unit 185a is connected to a node between the plurality of voltage dividing resistors 180a and 180b, and an output is connected to the node between the first main switch 120a and the second main switch 120b via the first bias resistor 190a. The first bias buffer unit 185a may apply, to the corresponding main switches 120a and 120b, voltages obtained by dividing, by the plurality of voltage dividing resistors 180a and 180b, a potential difference between the first sensing voltage output by the first sensing buffer unit 140 and the second sensing voltage output by the second sensing buffer unit 160a that is one of the plurality of second sensing buffer units 160. The first bias buffer unit 185a may receive a voltage at the node between the plurality of voltage dividing resistors 180a and 180b and apply, to the node between the first main switch 120a and the second main switch 120b, a voltage having a same voltage value as the received voltage.

An input of the second bias buffer unit 185b is connected to a node between the plurality of voltage dividing resistors 180c and 180d, and an output is connected to the node between the third main switch 120c and the fourth main switch 120d via the second bias resistor 190b. The second bias buffer unit 185b may apply, to the corresponding main switches 120c and 120d, voltages obtained by dividing, by the plurality of voltage dividing resistors 180c and 180d, a potential difference between the first sensing voltage output by the first sensing buffer unit 140 and the second sensing voltage output by the second sensing buffer unit 160b that is another one of the plurality of second sensing buffer units 160. The second bias buffer unit 185b may receive a voltage at the node between the plurality of voltage dividing resistors 180c and 180d and apply, to the node between the third main switch 120c and the fourth main switch 120d, a voltage having a same voltage value as the received voltage.

A current drive capability of each of the first bias buffer unit 185a and the second bias buffer unit 185b may be higher than a current drive capability of the first sensing buffer unit 140, the second sensing buffer unit 160a, and the second sensing buffer unit 160b. Each of the first bias buffer unit 185a and the second bias buffer unit 185b may have a configuration similar to the bias buffer unit 185 of the first exemplary configuration and similarly operate.

The outputs of the first bias buffer unit 185a and the second bias buffer unit 185b may be stopped by the control unit 100 in response to at least one of the first main switch 120a, the second main switch 120b, the third main switch 120c, or the fourth main switch 120d having been turned on. The outputs of the first bias buffer unit 185a and the second bias buffer unit 185b may be similarly stopped as in the bias buffer unit 185 of the first exemplary configuration. The switch apparatus 10 may further include the bias switch 195 similar to that of the first exemplary configuration between the output of the first bias buffer unit 185a and the node between the first main switch 120a and the second main switch 120b. The switch apparatus 10 may further include the bias switch 195 similar to that of the first exemplary configuration between the output of the second bias buffer unit 185b and the node between the third main switch 120c and the fourth main switch 120d.

The switch apparatus 10 of the present embodiment can switch on/off between the first main switch 120a and the second main switch 120b and between the third main switch 120c and the fourth main switch 120d and output the signal input to the first terminal 20 from one of the second terminal 30a or the second terminal 30b. The switch apparatus 10 turns on the output of the bias circuit 170 (the first bias buffer unit 185a, the second bias buffer unit 185b, and the third bias buffer unit 185c) while the first main switch 120a, the second main switch 120b, the third main switch 120c, and the fourth main switch 120d are turned off. With this configuration, the off-leak current can be reduced, and the concentration of the first voltage to the second main switch 120b and the third main switch 120c which are connected to the first terminal 20 is reduced by the voltage division in the bias circuit 170, so that the off-breakdown voltage of the entire switch apparatus 10 can be improved.

Note that the switch apparatus 10 of the present embodiment may include three or more second terminals 30 and second sensing buffer units corresponding to the respective second terminals 30 for the single first terminal 20.

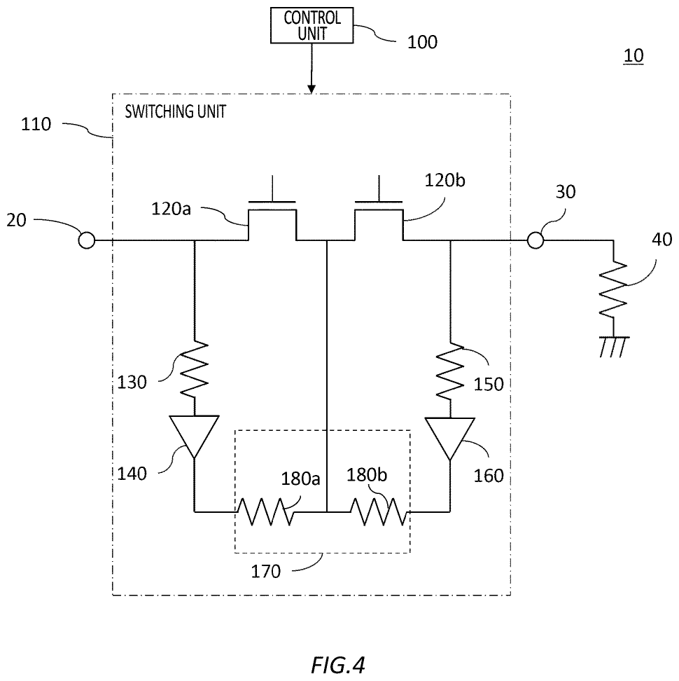

FIG. 4 illustrates a fourth exemplary configuration of the switch apparatus 10 according to the present embodiment. The switch apparatus 10 of the fourth exemplary configuration has a configuration and an operation similar to those of the switch apparatus 10 of the first exemplary configuration, but note that the bias buffer unit 185, the bias switch 195, and the bias resistor 190 are not included. Hereinafter, a difference from the first exemplary configuration will be mainly described.

The input of the first sensing buffer unit 140 is connected to the node between the first terminal 20 and the first main switch 120a via the first resistance 130, and the output is connected to one end of the voltage dividing resistor 180a. The first sensing buffer unit 140 may have a configuration similar to that of the first sensing buffer unit 140 of the first exemplary configuration and similarly operate. The first sensing buffer unit 140 may output a voltage by using a power supply having a same voltage value as the voltage value of the first voltage. With this configuration, the first sensing buffer unit 140 can apply a voltage in accordance with the first voltage alone between the main switches 120 and can more reliably divide the voltage into voltages.

One end of the second resistance 150 is connected to the node between the second terminal 30 and the second main switch 120b, and another end is connected to the input of the second sensing buffer unit 160. The second resistance 150 may have a same resistance value as the first resistance 130, and as an example, have a resistance value of 2 kΩ or more and 10 kΩ or less.

The output of the second sensing buffer unit 160 is connected to one end of the voltage dividing resistor 180b. The second sensing buffer unit 160 may have a configuration similar to the second sensing buffer unit 160 of the first exemplary configuration and similarly operate. The second sensing buffer unit 160 may output, to the bias circuit 170, the second sensing voltage having a same voltage value as the second voltage at the second terminal 30.

Another end of each of the plurality of voltage dividing resistors 180 is directly connected to the node between the first main switch 120a and the second main switch 120b. The resistance value of each of the plurality of voltage dividing resistors 180 may be lower than the resistance value of the first resistance 130.

The outputs of the first sensing buffer unit 140 and the second sensing buffer unit 160 may be stopped by the control unit 100 in response to at least one of the plurality of main switches 120 having been turned on. The outputs of the first sensing buffer unit 140 and the second sensing buffer unit 160 may be stopped by the control unit 100 by turning off a power supply which supplies electric power for the outputs of the first sensing buffer unit 140 and the second sensing buffer unit 160.

In the switch apparatus 10 of the present embodiment, reduction of the off-leak current and improvement of the off-breakdown voltage can be achieved by a simple circuit by the first sensing buffer unit 140.

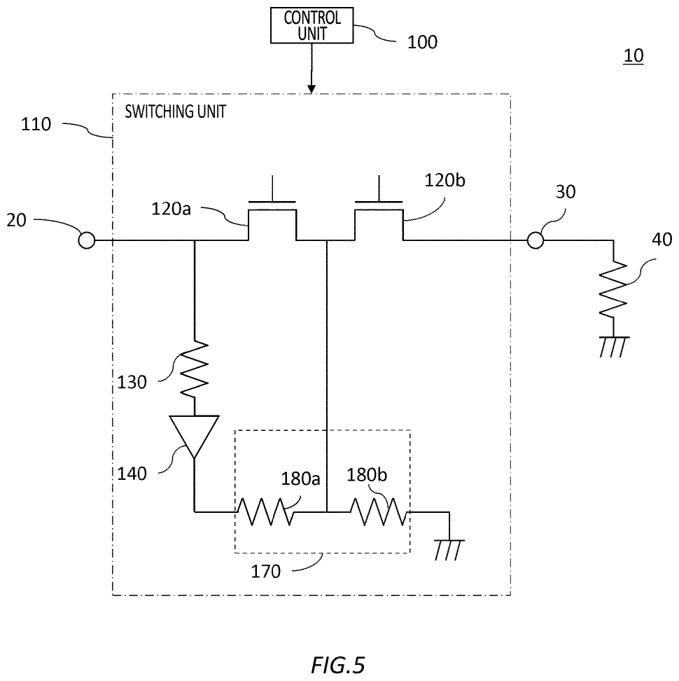

FIG. 5 illustrates a fifth exemplary configuration of the switch apparatus 10 according to the present embodiment. The switch apparatus 10 of the fifth exemplary configuration has a configuration and an operation similar to those of the switch apparatus 10 of the first exemplary configuration, but note that the second resistance 150, the second sensing buffer unit 160, the bias buffer unit 185, the bias resistor 190, and the bias switch 195 are not included. The switch apparatus 10 of the fifth exemplary configuration may cause a current to flow in a single direction from the first terminal 20 (input terminal) to the second terminal 30 (output terminal). Hereinafter, a difference from the first exemplary configuration will be mainly described.

The input of the first sensing buffer unit 140 is connected to the node between the first terminal 20 and the first main switch 120a via the first resistance 130, and the output is connected to one end of the voltage dividing resistor 180a. The first sensing buffer unit 140 may have a configuration similar to that of the first sensing buffer unit 140 of the first exemplary configuration and similarly operate. The first sensing buffer unit 140 may output a voltage by using a power supply having a same voltage value as the voltage value of the first voltage. With this configuration, the first sensing buffer unit 140 can apply a voltage in accordance with the first voltage alone between the main switches 120 and can more reliably divide the voltage into voltages.

One end of the second main switch 120b is connected to the first main switch 120a, and another end is connected to the second terminal 30. As being different from the first exemplary configuration, another end of the second main switch 120b is not connected to the voltage dividing resistor 180b.

Another end of each of the plurality of voltage dividing resistors 180 is directly connected to the node between the first main switch 120a and the second main switch 120b. One end of the voltage dividing resistor 180b in a subsequent stage is connected to a same reference potential (ground as an example) as a reference potential to which the load 40 is connected. Each of a resistance value of the plurality of voltage dividing resistors 180 may have a resistance value higher than a resistance of the load 40 and may be lower than the resistance value of the first resistance 130. With this configuration, the voltage input to the first terminal 20 can be reliably divided by the voltage dividing resistors 180 into voltages.

The output of the first sensing buffer unit 140 may be stopped by the control unit 100 in response to at least one of the plurality of main switches 120 having been turned on. The output of the first sensing buffer unit 140 may be stopped by the control unit 100 by turning off the power supply which supplies electric power for the output of the first sensing buffer unit 140.

In the unidirectional switch apparatus 10 of the present embodiment, the reduction of the off-leak current and the improvement of the off-breakdown voltage can be achieved by the simple circuit by the first sensing buffer unit 140.

Note that in at least one of the first exemplary configuration to the fifth exemplary configuration, a coil may be connected instead of at least one of the first resistance 130 or the second resistance 150. In this case too, the high frequency signal input to the first sensing buffer unit 140 or the second sensing buffer unit 160 can be reduced by the coil. In addition, in at least one of the first exemplary configuration to the fifth exemplary configuration, a coil may be connected in series to a preceding stage or a subsequent stage of at least one of the first resistance 130 or the second resistance 150.

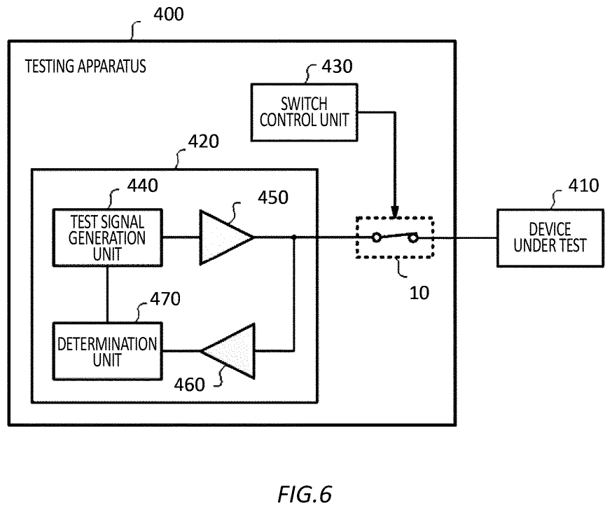

FIG. 6 illustrates a configuration example of a testing apparatus 400 according to the present embodiment together with a device under test 410. The testing apparatus 400 tests the device under test 410 such as an analog circuit, a digital circuit, a memory, or a system on chip (SOC). The testing apparatus 400 inputs, to the device under test 410, a test signal based on a test pattern for testing the device under test 410 and determines whether the device under test 410 is satisfactory or unsatisfactory based on an output signal that is output by the device under test 410 according to the test signal. The testing apparatus 400 includes a testing unit 420, the switch apparatus 10, and a switch control unit 430.

The testing unit 420 transmits and receives a signal to and from the device under test 410. The testing unit 420 includes a test signal generation unit 440, a driver 450, a comparator 460, and a determination unit 470. The test signal generation unit 440 generates the test signal for testing the device under test 410 to be output to the driver 450. The test signal generation unit 440 also generates an expected value corresponding to the generated test signal to be output to the determination unit 470.

The driver 450 supplies the test signal generated by the test signal generation unit 440 to the device under test 410. The comparator 460 acquires a logical value of a response signal output from the device under test 410 according to the supply of the test signal. The determination unit 470 compares the logical value acquired by the comparator 460 with the expected value to determine whether the device under test 410 is satisfactory or unsatisfactory.

The switch apparatus 10 is provided in a path between the driver 450 of the testing unit 420 and the device under test 410. In the switch apparatus 10, the first terminal 20 may be connected to the driver 450 of the testing unit 420, and the second terminal 30 may be connected to the device under test 410. The switch apparatus 10 establishes continuity or disconnection between the driver 450 and the device under test 410 according to a voltage of a control signal supplied from the switch control unit 430. The switch control unit 430 puts the main switch 120 of the switch apparatus 10 into an on state (continuity state) at a time of testing by the test signal generation unit 440 and puts the main switch 120 of the switch apparatus 10 into an off state (disconnection state) at times other than the time of the testing by the test signal generation unit 440.

For example, the switch control unit 430 transmits the control signal to the control unit 100 included in the switch apparatus 10. The control unit 100 switches on and off of the main switch 120 according to a control voltage of the received control signal.

While the present invention has been described above by way of the embodiments, the technical scope of the present invention is not limited to the above-described embodiments. It is apparent to persons skilled in the art that various alterations or improvements can be made to the above described embodiments. It is also apparent from description of the claims that the embodiments to which such alterations or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A switch apparatus which electrically connects or disconnects across a first terminal and a second terminal, the switch apparatus comprising:
a plurality of main switches connected in series between the first terminal and the second terminal;
a first sensing buffer unit to which a first voltage at the first terminal is input and which outputs a first sensing voltage in accordance with the first voltage; and
a bias circuit which divides, according to a number of the plurality of main switches, a potential difference between a voltage in accordance with a second voltage at the second terminal and the first sensing voltage into voltages and applies each of the voltages divided, to a corresponding one of the plurality of main switches.

2. The switch apparatus according to claim 1, further comprising:
a second sensing buffer unit to which the second voltage at the second terminal is input and which outputs a second sensing voltage in accordance with the second voltage, wherein
the bias circuit divides, according to the number of the plurality of main switches, a potential difference between the first sensing voltage and the second sensing voltage into voltages and applies each of the voltages divided, to the corresponding one of the plurality of main switches.

3. The switch apparatus according to claim 2, wherein
the bias circuit includes:
a plurality of voltage dividing resistors which are connected in series and which divide the potential difference between the first sensing voltage and the second sensing voltage into voltages.

4. The switch apparatus according to claim 3, wherein
the bias circuit includes:
one or more bias buffer units which apply each of voltages divided by the plurality of voltage dividing resistors to the corresponding one of the plurality of main switches.

5. The switch apparatus according to claim 4, wherein
an output of the bias buffer unit is stopped in response to at least one of the plurality of main switches having been turned on.

6. The switch apparatus according to claim 5, wherein
at least one of the plurality of main switches is turned on after the output of the bias buffer unit is stopped.

7. The switch apparatus according to claim 4, wherein
the bias circuit includes:
a bias resistor connected to the output of the bias buffer unit.

8. The switch apparatus according to claim 4, wherein
a current drive capability of the bias buffer unit is higher than a current drive capability of the first sensing buffer unit.

9. The switch apparatus according to claim 1, wherein
an output of the first sensing buffer unit is stopped in response to at least one of the plurality of main switches having been turned on.

10. The switch apparatus according to claim 9, wherein
at least one of the plurality of main switches is turned on after the output of the first sensing buffer unit is stopped.

11. The switch apparatus according to claim 3, wherein
a resistance value of each of the plurality of voltage dividing resistors is less than or equal to 10 kΩ.

12. The switch apparatus according to claim 3, further comprising:
a first resistance connected between the first terminal and the first sensing buffer unit, wherein
a resistance value of each of the plurality of voltage dividing resistors is less than a resistance value of the first resistance.

13. The switch apparatus according to claim 4, wherein
the second terminal includes a plurality of second terminals, each of which is identical to the second terminal,
the second sensing buffer unit includes a plurality of second sensing buffer units, each of which is identical to the second sensing buffer unit, and
the switch apparatus comprises:
the plurality of second terminals arranged for the first terminal concerned therewith; and
the plurality of second sensing buffer units respectively corresponding to the plurality of second terminals, and wherein
the bias circuit includes:
a first bias buffer unit which applies, to the corresponding one of the plurality of main switches, a voltage obtained by dividing, by the plurality of voltage dividing resistors, a potential difference between the first sensing voltage output by the first sensing buffer unit and the second sensing voltage output by one of the plurality of second sensing buffer units; and
a second bias buffer unit which applies, to the corresponding one of the plurality of main switches, a voltage obtained by dividing, by the plurality of voltage dividing resistors, a potential difference between the first sensing voltage output by the first sensing buffer unit and the second sensing voltage output by another one of the plurality of second sensing buffer units.

14. A testing apparatus which tests a device under test, the testing apparatus comprising:
a testing unit which transmits and receives a signal to and from the device under test; and
the switch apparatus according to claim 1 provided in a path between the testing unit and the device under test.
